(19) United States
(12) Patent Application Publication
(10) Pub. No.: US 2026/0088820 A1
(43) Pub. Date: Mar. 26, 2026

(54) ISOLATOR

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Bowen DANG, Kawasaki Kanagawa (JP); Shoji OOTAKA, Yokohama Kanagawa (JP); Shinichiro ISHIZUKA, Sumida Tokyo (JP); Reiji TAGOMORI, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/324,245

(22) Filed: Sep. 10, 2025

(30) Foreign Application Priority Data
Sep. 20, 2024 (JP) 2024-164310
Mar. 17, 2025 (JP) 2025-042677

(51) Int. Cl. H03K 19/00; H03K 9/02; H03K 19/0175; H03M 3/00

(52) U.S. Cl. CPC H03K 19/0016; H03K 9/02; H03K 19/017509; H03M 3/32

(57) ABSTRACT

An isolator according to one embodiment includes: a ΔΣ modulation analog-to-digital converter converts the input analog signal into a digital data signal of a pulse train corresponding to the amplitude of the input analog signal, and outputs the digital data signal; an attribute signal detection circuit detects an attribute of the input analog signal and outputs input attribute information related to the attribute of the input analog signal; a high speed feedback encoder encodes the digital data signal based on the input attribute information and outputs a first encoded signal; an edge encoder outputs a second encoded signal; an insulated transmission circuit outputs a transmission signal transmitted through the insulation unit in response to the second encoded signal; and a demodulation circuit outputs a demodulated digital data signal obtained by demodulating the second encoded signal and/or the input attribute information, based on the transmission signal.

### CROSS-REFERENCE TO RELATED APPLICATIONS

This application is based upon and claims the benefit of priority from the prior Japanese Patent Applications No. 2024-164310, filed on Sep. 20, 2024 and No. 2025-042677, filed on Mar. 17, 2025, the entire contents of which are incorporated herein by reference.

### FIELD

The present embodiment relates to an isolator.

### BACKGROUND

Generally, an isolator comprises, for example, a primary circuit on the input side and a secondary circuit on the output side, separated by an insulating layer. Here, the target primary circuit digitizes an analog signal input from the target device, modulates it, and then transmits it to the insulating layer. The secondary circuit demodulates the data transmitted through the insulating layer and outputs it.

An example of such an isolator is an isolation amplifier, whose primary circuit uses, for example, a ΔΣ modulation analog-to-digital converter (ΔΣ ADC) to digitize an analog input signal. A ΔΣ ADC is a circuit that oversamples an analog signal, quantizes it, and ΔΣ modulates it to convert it into a digital signal or pulse train according to the amplitude of the analog signal, and outputs it. Since quantization noise in the output signal of this ΔΣ ADC is biased toward the high-frequency side due to ΔΣ modulation, the quantization noise can be effectively removed, for example, by installing a low-pass filter in the secondary circuit.

### BRIEF DESCRIPTION OF THE DRAWINGS

FIG. 1 is a diagram showing an example of the configuration of an isolator according to a first embodiment.

FIG. 2 is a diagram showing an example of a signal waveform in the isolator shown in FIG. 1.

FIG. 3 is a diagram showing another example of a signal waveform in the isolator shown in FIG. 1.

FIG. 4 is a diagram showing an example of a determination by a demodulation circuit regarding the type of data series of a second encoded signal and the attributes of an input analog signal corresponding to the data series.

FIG. 5 is a diagram showing an example of the configuration of an isolator according to a second embodiment.

FIG. 6 is a diagram showing an example of a signal waveform in the isolator shown in FIG. 5.

FIG. 7 is a diagram showing an example of a specific configuration of a data rewrite circuit R of the isolator shown in FIG. 5.

FIG. 8 is a diagram showing an example of a specific configuration of a demodulation circuit of the isolator shown in FIG. 5.

### DETAILED DESCRIPTION

An object of one embodiment is to provide an isolator that can reduce delays in signal transmission while reducing power consumption.

An isolator according to one embodiment includes:
a ΔΣ modulation analog-to-digital converter that receives an input analog signal, converts the input analog signal into a digital data signal of a pulse train corresponding to the amplitude of the input analog signal, and outputs the digital data signal;
an attribute signal detection circuit that detects an attribute of the input analog signal and outputs input attribute information related to the attribute of the input analog signal;
a high speed feedback encoder that encodes the digital data signal based on the input attribute information and outputs a first encoded signal;
an edge encoder that receives the first encoded signal, edge-encodes the first encoded signal, and outputs a second encoded signal;
an insulated transmission circuit that has an insulation unit electrically insulated between an input and an output, receives the second encoded signal, and outputs a transmission signal transmitted through the insulation unit in response to the second encoded signal; and
a demodulation circuit that receives the transmission signal, and outputs a demodulated digital data signal obtained by demodulating the second encoded signal and/or the input attribute information, based on the transmission signal.

The isolator according to the embodiment will be described in detail below with reference to the attached drawings. Note that the present invention is not limited to these embodiments.

### First Embodiment

### [Isolator]

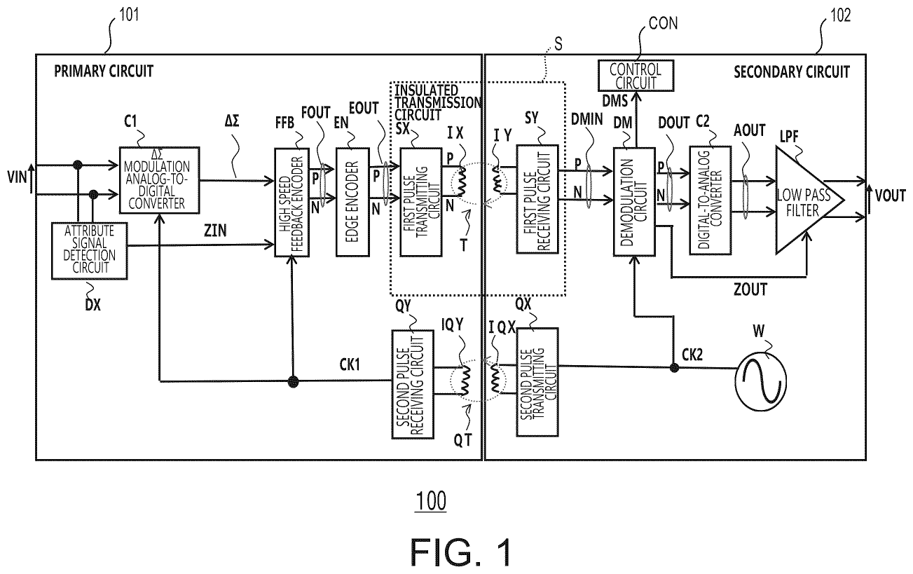

FIG. 1 shows an example of the configuration of an isolator according to the first embodiment.

As shown in FIG. 1, the isolator 100 of the first embodiment is an isolated amplifier having a primary circuit 101 located on the input side and a secondary circuit 102 located on the output side, with an insulated transmission circuit S in between.

For example, as shown in FIG. 1, the specific circuit configuration of this isolator 100 includes a ΔΣ modulation analog-to-digital converter C1, an attribute signal detection circuit DX, a high speed feedback encoder FFB, an edge encoder EN, an insulated transmission circuit S, a demodulation circuit DM, a control circuit CON, a low pass filter LPF, a digital-to-analog converter C2, a clock signal generating circuit W, a second pulse transmitting circuit QX, a second pulse receiving circuit QY, and a transformer QT.

For example, as shown in FIG. 1, the ΔΣ modulation analog-digital converter C1, the attribute detection circuit DX, the high speed feedback encoder FFB, the edge encoder EN, the first pulse transmitting circuit SX and the inductor IX of the transformer T of the insulated transmission circuit S, and the second pulse receiving circuit QY and the inductor QIY of the transformer QT are arranged in the primary circuit 101.

Furthermore, for example, as shown in FIG. 1, the demodulation circuit DM, the control circuit CON, the low-pass filter LPF, the digital-to-analog converter C2, the first pulse receiving circuit SY of the insulated transmission circuit S and the inductor IY of the transformer T, and the second pulse transmitting circuit QX and the inductor QIX of the transformer QT are arranged in the secondary circuit 102.

These components of the isolator 100 are described in detail below.

### [ΔΣ Modulation Analog-to-Digital Converter]

The ΔΣ modulation analog-to-digital converter C1 receives the input analog signal VIN, as shown in FIG. 1. The ΔΣ modulation analog-to-digital converter C1 then oversamples the input analog signal VIN in synchronization with the first clock signal CK1, quantizes it, and ΔΣ-modulates it, converting it into a digital data signal ΔΣ that is a pulse train according to the amplitude of the input analog signal VIN, and outputs the digital data signal ΔΣ.

### [Attribute Signal Detection Circuit]

The attribute signal detection circuit DX receives the input analog signal VIN, as shown in FIG. 1. The attribute signal detection circuit DX detects the attributes of the input analog signal VIN and outputs input attribute information ZIN relating to the attributes of the input analog signal VIN to the high speed feedback encoder shown below.

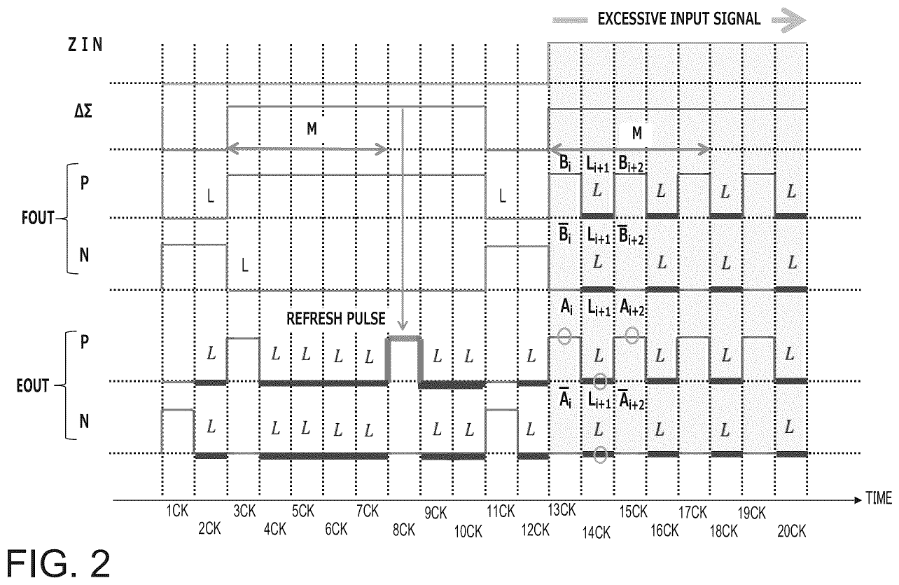

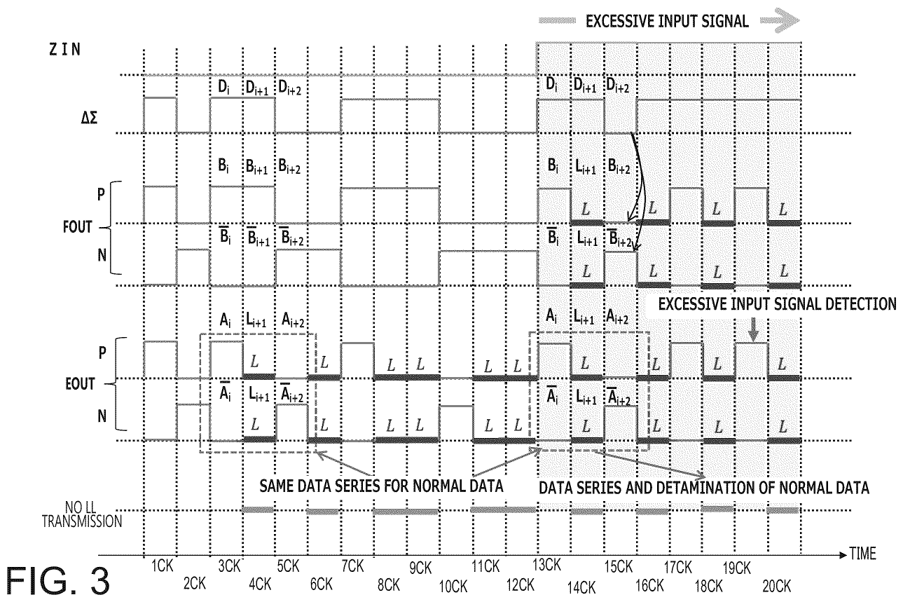

For example, when the amplitude of the input analog signal VIN is equal to or less than an excessive threshold set based on the input range of the ΔΣ modulation analog-to-digital converter C1, the attribute signal detection circuit DX outputs input attribute information ZIN (second polarity “L” in the examples of FIGS. 2 and 3 described below) indicating the first attribute that the input analog signal VIN is a normal data signal input.

On the other hand, when the amplitude of the input analog signal VIN is greater than the excessive threshold, the attribute signal detection circuit DX outputs input attribute information ZIN indicating a second attribute (first polarity “H” in the examples of FIGS. 2 and 3 described below) that the input analog signal VIN is an excessive input signal.

### [High Speed Feedback Encoder]

The high speed feedback encoder FFB receives, for example, a digital data signal ΔΣ and input attribute information ZIN as input, as shown in FIG. 1. This high speed feedback encoder FFB encodes the digital data signal ΔΣ based on the input attribute information ZIN in synchronization with the first clock signal CK1, and outputs a 2-bit first encoded signal FOUT.

For example, when the input attribute information ZIN indicates the first attribute, the high speed feedback encoder FFB is configured to output a first encoded signal FOUT that is encoded according to the polarity of the data series of the digital data signal ΔΣ.

On the other hand, when the input attribute information ZIN indicates the second attribute, the high speed feedback encoder FFB outputs a first encoded signal FOUT that is encoded so as to forcibly rewrite part of the data in the data series of the digital data signal ΔΣ (for example, data at every other clock of the first clock signal CK1) to rewrite data of a preset value (for example, 2-bit data “LL”).

Therefore, the first encoded signal FOUT, which includes a data series including rewrite data of this predetermined value, includes information on the second attribute related to an excessive input signal. It is noted that, although excessive input has been used as an example of input attribute information, this is not limited to this.

### [Edge Encoder]

The edge encoder EN is configured to receive the first encoded signal FOUT. This edge encoder EN edge-encodes the first encoded signal FOUT and outputs a 2-bit second encoded signal EOUT (when the edge encoder EN detects an edge of a pulse of the first encoded signal FOUT, the edge encoder EN generates a pulse of the second encoded signal EOUT).

Also, as shown in FIG. 2 described below, this edge encoder EN performs a refresh operation every refresh period (number of periods) M, and generates a refresh pulse in the second encoded signal EOUT.

### [Insulated Transmission Circuit]

The insulated transmission circuit S has insulation units SX, SY, and T that are electrically insulated between the input and output, as shown in FIG. 1, for example. The insulated transmission circuit S receives the second encoded signal EOUT and outputs the transmission signal DMIN transmitted through the insulation unit SX, SY, and T in response to the second encoded signal EOUT.

This insulation unit SX, SY, T comprises, for example, a first pulse transmission circuit SX, a transformer T, a first pulse receiving circuit SY, and a transformer T, as shown in FIG. 1.

The first pulse transmission circuit SX receives the second encoded signal EOUT. The first pulse transmission circuit SX flows a current corresponding to the second encoded signal EOUT through an inductor IX at one end of the transformer T. In other words, the first pulse transmission circuit SX generates a pulse signal by flowing a current between the P terminal and the N terminal to which the inductor IX is connected. A signal is transmitted to an inductor IY at the other end of the transformer T via a magnetic field in accordance with the current flowing through the inductor IX at one end of the transformer T.

Then, the first pulse receiving circuit SY regenerates the second encoded signal EOUT based on the signal transmitted to this inductor IY and outputs the second encoded signal EOUT as the transmission signal DMIN.

In particular, this insulated transmission circuit S is configured to transmit a transmission signal DMIN, which is a pulse of a data series of data of a first polarity “H” or a second polarity “L” synchronized with the first clock signal CK1, in response to the second encoded signal EOUT.

Furthermore, the insulated transmission circuit S is configured to transmit a transmission signal DMIN that does not include a pulse within a predetermined clock period defined by the first clock signal CK1 in response to the second encoded signal EOUT.

In the example shown in FIG. 1, the insulated transmission circuit S is configured using a magnetic coupling method. However, this is not limited to this, and optical coupling or capacitive coupling may also be used.

### [Demodulation Circuit]

The demodulation circuit DM is configured to receive the transmission signal DMIN as an input, as shown in FIG. 1. The demodulation circuit DM is configured to output a demodulated digital data signal DOUT obtained by demodulating the second encoded signal and/or input attribute information based on the transmission signal DMIN in synchronization with the second clock signal CK2.

For example, as shown in FIG. 2 described below, if the two bits of data before and after the two-bit rewrite data “LL” of a predetermined value rewritten by the high speed feedback encoder FFB in the second encoded signal EOUT (i.e., the transmission signal DMIN) are respectively the first data and the second data, and if the polarity (value) of the first data is equal to the polarity (value) of the second data, the demodulation circuit DM determines that the input attribute information ZIN indicates that the input analog signal VIN is an excessive input signal, that is, a second attribute, and outputs demodulation attribute information ZOUT according to this determination result.

Furthermore, as shown in FIG. 3 described below, in this first embodiment, the first data series of the second encoded signal EOUT obtained by encoding the digital data signal ΔΣ, corresponding to the input attribute information ZIN indicating the first attribute, by the edge encoder EN, may be the same as the second data series of the second encoded signal EOUT obtained by encoding the digital data signal ΔΣ, corresponding to the input attribute information ZIN indicating the second attribute, by the edge encoder EN.

In this case, the demodulation circuit DM outputs a demodulated digital data signal DOUT that is demodulated as a data series of the input analog signal VIN of a normal data signal based on the data series of the transmission signal corresponding to the second encoded signal EOUT of the second data series (i.e., the demodulation circuit DM outputs data corresponding to the excessive input signal as data of the normal data signal).

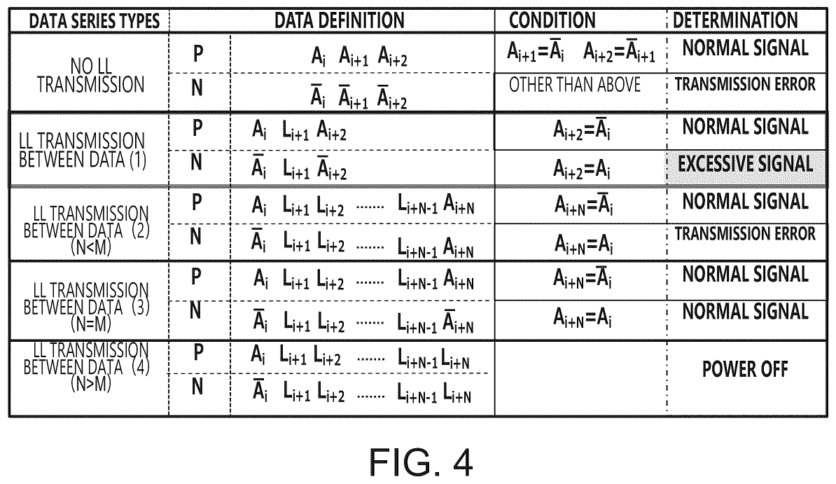

Furthermore, as shown in FIG. 4 described below, in this embodiment, when the demodulation circuit DM determines that a transmission error has occurred due to a malfunction of the isolator 100 or the like, based on the transmission signal DMIN corresponding to the second encoded signal EOUT, the demodulation circuit DM outputs an error signal DMS.

As described below, the first clock signal CK1 that determines the operation of the ΔΣ modulation analog-to-digital converter C1 and the high speed feedback encoder FFB is synchronized with the second clock signal CK2 that determines the operation of the demodulation circuit DM.

As a result, the operation of the ΔΣ modulation analog-to-digital converter C1 and the high speed feedback encoder FFB is synchronized with the operation of the demodulation circuit DM.

### [Control Circuit]

The control circuit CON receives the error signal DMS output by the demodulation circuit DM. The control circuit CON executes control operations such as turning off the power to the secondary circuit 102 in response to the error signal DMS, to stop the output of the isolator 100.

### [Digital-to-Analog Converter]

The digital-to-analog converter C2 is configured to receive the demodulated digital data signal DOUT. The digital-to-analog converter C2 converts the demodulated digital data signal DOUT into a demodulated analog signal AOUT and outputs the demodulated analog signal AOUT.

### [Low-Pass FILTER]

The demodulated analog signal AOUT is input to the low-pass filter LPF. The low-pass filter LPF then removes harmonics from the demodulated analog signal AOUT, regenerates the input analog signal VIN input to the primary circuit 101, and outputs this input analog signal VIN as a differential output of the secondary circuit 102.

Furthermore, the low-pass filter LPF is configured to receive the demodulation attribute information ZOUT signal output by the demodulation circuit DM.

For example, when the demodulation attribute information ZOUT is the first polarity “H” indicating the second attribute, the low-pass filter LPF makes the common-mode potential of the differential output signal VOUT of the low-pass filter LPF higher than normal, and transmits information regarding the excessive input signal to a CPU or the like located downstream.

On the other hand, when the demodulation attribute information ZOUT is the second polarity “L” indicating the first attribute, the low-pass filter LPF sets the common-mode potential of the differential output signal VOUT of the low-pass filter LPF to a normal potential and transmits information indicating that it is a normal data signal to a CPU or the like located in a downstream stage.

### [Clock Signal Generating Circuit]

The clock signal generating circuit W generates and outputs the second clock signal CK2. The second clock signal CK2 generated by the clock signal generating circuit W is supplied to the demodulation circuit DM.

Then, this second clock signal CK2 is transmitted from the secondary circuit 102 to the primary circuit 101 as the first clock signal CK1 via the second pulse transmitting circuit QX, the transformer QT (inductors QIX, QIY), and the second pulse receiving circuit QY.

Therefore, as already described, the first clock signal CK1 that determines the operation of the ΔΣ modulation analog-to-digital converter C1 and the high speed feedback encoder FFB is synchronized with the second clock signal CK2 that determines the operation of the demodulation circuit DM.

In other words, the operations of the ΔΣ modulation analog-to-digital converter C1 and the high speed feedback encoder FFB are synchronized with the operation of the demodulation circuit DM.

### [Isolator Operation]

Next, an example of the operation of the isolator 100 having the above configuration will be described. Here, FIG. 2 shows an example of a signal waveform in the isolator shown in FIG. 1.

For example, as shown in FIG. 2, when the input attribute information ZIN indicates the first attribute “L”, the input analog signal VIN is not an excessive input signal but a normal data signal within the input range of the ΔΣ modulation analog-to-digital converter C1.

The high speed feedback encoder FFB converts the digital data signal ΔΣ into two bits and outputs the first encoded signal FOUT, here P and N.

At this time, if the digital data signal ΔΣ is of the first polarity “H”, the 2-bit data of PN of the first encoded signal FOUT is converted to the first polarity “HL”. On the other hand, if the digital data signal ΔΣ is of the second polarity “L”, the 2-bit data of the first encoded signal FOUT is converted to the second polarity “LH”.

As mentioned above, the first encoded signal FOUT output by the high speed feedback encoder FFB has two bits of PN, which are written in a specific order.

Then, the edge encoder EN edge encodes this first encoded signal FOUT and outputs a second encoded signal EOUT of 2 bits of PN.

Then, the first pulse transmission circuit SX passes currents of different polarities between the P terminal and N terminal of the inductor IX depending on the polarity of this second encoded signal EOUT, which is specified by two bits. Then, the first pulse receiving circuit SY outputs the transmission signal DMIN, which is specified by two bits, based on the polarity of the current flowing through the inductor IY corresponding to the polarity of the current through the inductor IX.

On the other hand, as shown in FIG. 2, when the input attribute information ZIN has the first polarity “H” indicating the second attribute, that is, when the input analog signal VIN is outside the input range of the ΔΣ modulation analog-to-digital converter C1 and is a so-called excessive input signal, the high speed feedback encoder FFB executes special encoding.

For example, at time 13CK in FIG. 2, when the input attribute information ZIN becomes the first polarity “H” indicating the second attribute, the high speed feedback encoder FFB outputs data obtained by converting the data of the digital data signal ΔΣ to, for example, “HL” (or “LH”) as described above. After that, the high speed feedback encoder FFB rewrites the data of the digital data signal ΔΣ to rewrite data “LL” every other clock of the first clock signal CK1 and outputs it (times 14CK, 16CK, 18CK, and 20CK in FIG. 2).

Then, the high speed feedback encoder FFB converts the data of the non-rewriteable digital data signal ΔΣ every other clock of the clock signal CK1 to “HL” (or “LH”) and outputs it (times 15CK, 17CK, and 19CK in FIG. 2).

To identify the rewritten data “LL” as described above, the first encoded signal FOUT requires 2 bits of data.

For example, when the data of the second encoded signal EOUT becomes “LL” in response to the data of the first encoded signal FOUT being “LL”, the first pulse transmission circuit SX of the insulated transmission circuit S does not output any current for one period of the first clock signal CK1.

The demodulation circuit DM of the secondary circuit 102 receives as input a second clock signal CK2 having the same period as the first clock signal CK1. Therefore, if no pulse signal is input to the demodulation circuit DM for one period of the second clock signal CK2, the demodulation circuit DM determines that data “LL”has been input.

Here, for example, as shown in FIG. 2, in the section from the beginning to time 12CK, the data of the digital data signal ΔΣ is converted based on the above rules and output to the first encoded signal FOUT. From time 13CK onwards, when the input attribute information ZIN becomes the first polarity “H” indicating the second attribute, the data of the digital data signal ΔΣ and the rewritten data “LL”are repeatedly output.

If the clock of the first clock signal CK1 at which the input attribute information ZIN becomes data “H” indicating the second attribute is the i-th clock, then the i-th first encoded signal FOUT is data converted from the data of the digital data signal ΔΣ, so the P terminal data of the output of the first encoded signal FOUT is “Bᵢ” and the N terminal data is “B̅ᵢ”.

Here, data “Bᵢ” represents the first polarity “H”, and data “B̅ᵢ” represents the second polarity “L”, which is the opposite polarity of data “Bᵢ”. And the data of the (i+1)th P terminal and N terminal are both “Lᵢ₊”. The data of the P terminal and N terminal of the (i+2)th digital data signal ΔΣ output are “H”, “Bᵢ₊”, and “B̅ᵢ₊”, respectively, with “Bᵢ₊” representing “H” and “B̅ᵢ₊” representing the opposite polarity “L” of “Bᵢ₊”. As long as the input attribute information ZIN remains the first polarity “H” indicating the second attribute, the high speed feedback encoder FFB executes the above data conversion.

Here, when the input attribute information ZIN is data “L” indicating the first attribute, the first pulse transmission circuit SX outputs a current signal to the transformer T in response to the P and N terminal signals of the second encoded signal EOUT which is edge-encoded from the first encoded signal FOUT.

On the other hand, the first pulse transmission circuit SX outputs a current signal to the transformer T with one data interval when the input attribute information ZIN is data “H” indicating the second attribute, but does not output current to the transformer T for the remaining half, i.e., when the P and N terminals of the output of the first pulse transmission circuit SX are “LL”.

Assuming that it takes one clock period for transmission from the first pulse transmission circuit SX to the first pulse receiving circuit SY, in addition to the one clock period for this transmission, the demodulation circuit DM outputs the demodulated digital data signal DOUT and demodulation attribute information ZOUT with a delay of three clocks of the second clock signal CK2. This is because the demodulation circuit DM needs data for a continuous three clock period to determine the demodulation attribute information ZOUT.

In this first embodiment, the demodulation circuit DM recognizes the data of the transmission signal DMIN corresponding to the data series “Aᵢ-Lᵢ₊-Aᵢ₊” of the P terminal of the three-clock second encoded signal EOUT and the data series “Āᵢ-Lᵢ₊-Āᵢ₊” of the N terminal.

As described above, when the input attribute information ZIN is data “L” indicating the first attribute, a current is output to the transformer T for each pulse of the first clock signal CK1 in accordance with the data of the digital data signal ΔΣ for each clock of the clock signal CK1. In order to reduce power consumption, it is effective to use a method of reducing the number of times that a current is output to the transformer T.

As already described, the isolator 100 has a transmission system equipped with an edge encoder EN between the high speed feedback encoder FFB and the insulated transmission circuit S.

The digital data signal ΔΣ output by the ΔΣ modulation analog-to-digital converter C1 is such that the first two data bits from the left (time 2CK) are “L”, and after eight consecutive data bits from the third data bit from the left (time 3CK) are “H”, the 11th and 12th data bits (time 11CK, time 12CK) change to “L”. At this time, the data of the input attribute information ZIN becomes “L”with the second polarity.

Then, the digital data signal ΔΣ becomes “H” for eight consecutive periods from the 13th (time 13CK) to the 20th (time 20CK). At this time, the data of the input attribute information ZIN has the first polarity “H”. When the data of the input attribute information ZIN has the first polarity “H”, the high speed feedback encoder FFB converts the digital data signal ΔΣ into a first encoded signal FOUT in which 2-bit data and the rewrite data “LL” signal appear alternately. Therefore, no data conversion is performed by the edge encoder EN (i.e., the edge encoder EN does not convert the data of the first encoded signal FOUT, but outputs it as it is as the second encoded signal EOUT).

On the other hand, when the input attribute information ZIN is data “L” indicating the first attribute, the high speed feedback encoder FFB simply converts the digital data signal ΔΣ into 2-bit data, and the continuous data series is maintained as is. The edge encoder EN sends data only when there is a data transition.

Here, for example, the data conversion from the second data (time CK2) to the fourth data (time CK4) in FIG. 2 will be described in detail.

As shown in FIG. 2, the second (CK2) to fourth (CK4) data of the first encoded signal FOUT output by the ΔΣ modulation analog-to-digital converter C1 consists of the data “LH” followed by the data “HL”, “HL” at the P and N terminals.

Then, the second (at time CK2) to fourth (at time CK4) data of the second encoded signal EOUT output by the edge encoder EN are consecutive data “LL”. Therefore, after the data “LL”, the data “HL” and “LL”appear at the P and N terminals.

The second data (CK2) of the second encoded signal EOUT is “LL” because the second data (time CK2) of the digital data signal ΔΣ is the same as the first data.

The eighth data from the left (time CL8) of the second encoded signal EOUT output by the edge encoder EN is “HL” to take into account the refresh operation.

In the example shown in FIG. 2, for the sake of explanation, the refresh period M is set to six periods of the first clock signal CK1. The refresh period M indicates the number of periods of each data signal, i.e., the number of clock periods of the first clock signal CK1.

The refresh operation of the edge encoder EN is executed when the same data occurs consecutively, and the second encoded signal EOUT during the refresh is the same signal as the first encoded signal FOUT at that time.

On the other hand, when the excessive input signal in FIG. 2 is input (time 13CK to 20CK), if the data of the digital data signal ΔΣ continues to be “H”, the second encoded signal EOUT alternates between the same data, in this case data “HL”, and the rewrite data “LL”.

Then, in the second encoded signal EOUT (i.e., the transmission signal DMIN), when the two bits of data before and after the two-bit rewrite data “LL” of a predetermined value rewritten by the already-mentioned high speed feedback encoder FFB are respectively the first data and the second data, if the polarity (value) of the first data and the polarity (value) of the second data are equal, the demodulation circuit DM determines that the input attribute information ZIN indicates that the input analog signal VIN is an excessive input signal, that is, a second attribute, and outputs demodulation attribute information ZOUT according to this determination result.

In this way, unless the number of cycles M of the refresh operation is set to 2 clocks, the refresh operation is not executed, so there is no confusion between the data “L” of the input attribute information ZIN, i.e., the data when a normal data signal is input, and the data “H” of the input attribute information ZIN, i.e., the data when an excessive input signal is input.

Next, FIG. 3 is a diagram showing another example of the signal waveform in the isolator shown in FIG. 1. With reference to this FIG. 3, the data conversion of the high speed feedback encoder FFB and the edge encoder EN will be described with respect to the third, fourth, and fifth (3 CK, 4 CK, 5 CK) data “Dᵢ, Dᵢ₊, Dᵢ₊” of the digital data signal ΔΣ from the beginning when the data of the input attribute information ZIN is “L” and the thirteenth, fourteenth, and fifteenth (time 1 CK to 1 CK) data “Dᵢ, Dᵢ₊, Dᵢ₊” of the digital data signal ΔΣ from the beginning when the data of the input attribute information ZIN is “H”.

In both cases where the input attribute information ZIN is data “L” and data “H”, the data series of the digital data signal ΔΣ is Dᵢ=H, Dᵢ₊=H, Dᵢ₊=L

First, in the case of a normal data signal in which the input attribute information ZIN is data “L” indicating the first attribute, the digital data signal ΔΣ is simply converted to two bits by the high speed feedback encoder FFB, so the data series of the first encoded signal FOUT becomes “HL”, “HL”, and “LH”.

Then, the edge encoder EN converts consecutive identical data into “LL”, so the data series of the second encoded signal EOUT output by the edge encoder EN becomes “HL”, “LL”, and “LH”.

On the other hand, in the case of an excessive input signal in which the data of the input attribute information ZIN is the first polarity “H”, the digital data signal ΔΣ is also converted to two bits by the high speed feedback encoder FFB. However, in this case, the high speed feedback encoder FFB forcibly inserts data “LL” at an interval of one clock of the first clock signal CK1. Therefore, the data of the data series of the first encoded signal FOUT becomes “HL”, “LL”, and “LH”.

Then, since there is no consecutive identical data in the edge encoder EN, it is output as is, and the data in the data series of the second encoded signal EOUT becomes “HL”, “LL”, and “LH”.

In this way, these two data series of the second encoded signal EOUT have the same data content. However, one data series is the data series when the input attribute information ZIN has the second polarity “L” indicating the first attribute, and the other data series is the data when the input attribute information ZIN has the first polarity “H” indicating the second attribute. The attribute of the input analog signal VIN cannot be determined from these data series.

As mentioned above, the attribute of the input analog signal VIN indicates the presence or absence of an excessive input signal. However, if it is not possible to determine whether the input analog signal VIN is an excessive input signal, it becomes difficult to quickly convey the attribute indicating an excessive input signal to a CPU or other device connected downstream of the isolator 100.

In this way, if FFB encoding, which transmits information about the attributes of excessive input signals at high speed, and edge encoding, which enables low power consumption, are connected in series, it becomes impossible to determine whether or not excessive input signal information is present for certain input data.

Therefore, in this first embodiment, as described below, when excessive input information, i.e., attribute information cannot be determined, specific attribute information is set in advance to be given priority.

It is noted that in this first embodiment, when the attribute information is the presence or absence of excessive input, the prioritized attribute information is the absence of an excessive input signal (first attribute). As a result, a difference occurs between the digital data signal ΔΣ output by the ΔΣ modulation analog-to-digital converter C1 and the demodulated digital data signal DOUT demodulated by the demodulation circuit DM only when the analog signal VIN is an excessive input signal (second attribute). In that case, since the input analog signal VIN is an excessive input signal, it is considered that there is little need to correctly transmit the information of the digital data signal ΔΣ.

Here, FIG. 4 shows an example of the determination by the demodulation circuit regarding the type of data series of the second encoded signal (transmission signal) and the attributes of the input analog signal corresponding to that data series.

First, for example, there is a case where the data of the transmission signal DMIN corresponding to the encoded signal EOUT changes for each clock of the first clock signal CK1, whose type of data series shown in FIG. 4 is “no LL transmission”, that is, Aᵢ₊=Āᵢ, Aᵢ₊=Āᵢ₊.

Under these conditions, the demodulation circuit DM can determine, based on the transmission signal DMIN, that the input analog signal VIN is a normal data signal within the range of the ΔΣ modulation analog-to-digital converter C1 and is not an excessive input signal.

On the other hand, if the condition is not Aᵢ₊=Āᵢ, Aᵢ₊=Āᵢ₊, the same data will continue. However, if the digital data signal ΔΣ is edge encoded, the same data cannot continue. Therefore, when the demodulation circuit DM detects a transmission signal DMIN that meets this condition, it determines that a transmission error has occurred.

Next, the case where the type of data series shown in FIG. 4 is “LL transmission between data (1)” is a case where the data series has one LL transmission inserted between consecutive data. In this case, the presence or absence of an excessive input signal cannot be determined under the condition Aᵢ₊=Āᵢ.

However, if Aᵢ₊=Aᵢ, there is no polarity reversal of the data, so it is determined that it is not an edge-encoded normal data signal. Therefore, under this condition, the demodulation circuit DM can conclude that if there is no transmission error, it is an excessive input signal. On the other hand, under the condition Aᵢ₊=Āᵢ, the demodulation circuit DM cannot determine the presence or absence of an excessive input signal based on the transmission signal DMIN, but determines that it is a normal data signal.

The data series of the digital data signal ΔΣ under these conditions is, for example, “LLHHLLHH . . .”. However, this data series occurs when the input analog signal VIN is 0. Therefore, this data series of the digital data signal ΔΣ occurs frequently.

If this data series are determined to be an excessive input signal, the system would frequently stop, making it impractical. Furthermore, when an excessive input signal is present, the data of the digital data signal ΔΣ is likely to be stuck to one polarity or the other. For this reason, when an excessive input signal is input, the polarity of the data of the digital data signal ΔΣ is unlikely to be reversed.

In an ideal ΔΣ modulation analog-to-digital converter C1 with stable response, there would be no reversal of polarity in the data when an excessive input signal is input. However, if the input of an excessive input signal temporarily causes a reversal of the polarity of the data (time 15 CK in FIG. 3), the reversal will delay the detection of the excessive input. On the other hand, as shown in FIG. 3, the delay before the excessive input signal is detected is only a few clocks, so it can be said that there is no major problem due to the delay in detecting the excessive input signal.

Next, the case where the type of data series shown in FIG. 4 is “Inter-data LL transmission (2)” is a case where the number of consecutive LL transmissions N is smaller than the number of cycles M for performing two or more refreshes. In this case, since there are two or more LL transmissions, there is no judgment of an excessive input signal.

According to the edge encoding conditions, when the condition A_{i+N}=Āᵢ holds, the demodulation circuit DM determines that the input analog signal VIN is a normal data signal. And when the condition A_{i+N}=Aᵢ holds, the demodulation circuit DM determines that there is a transmission error.

Next, the case where the type of data series shown in FIG. 4 is “Inter-data LL transmission (3)” is the case where the number of consecutive LL transmissions N is equal to the period M in which two or more refreshes are performed. In this case, since there are two or more LL transmissions, there is no judgment of an excessive input signal. However, there are cases of both polarity inversion and refreshing of a normal data signal, but both fall within the category of a normal data signal, and the demodulation circuit DM judges it to be a normal data signal.

Next, the case where the type of data series shown in FIG. 4 is “Inter-data LL transmission (4)” is a case where the number of consecutive LL transmissions N is greater than the number of cycles M for refreshing, which is set to 2 or more. In this case, since there have been two or more LL transmissions, there is no judgment of an excessive input signal, and the refresh cycle M has also passed. Therefore, the demodulation circuit DM determines that an abnormality has occurred on the data transmission side. Here, since no data is being transmitted, the demodulation circuit DM determines that the power is off.

That is, when a data series has one LL transmission (one clock period) inserted between the data of the transmission signal DMIN corresponding to the second encoded signal EOUT, the demodulation circuit DM determines that the input signal is an excessive input signal if the condition Aᵢ₊=Aᵢ holds. On the other hand, the demodulation circuit DM determines that the input signal is a normal data signal if the condition Aᵢ₊=Āᵢ holds.

As described above, the isolator 100 according to the first embodiment performs edge-encoded transmission, which is advantageous for reducing power consumption, for pulse transmission with encoding of an excessive input signal. Furthermore, the isolator 100 makes a rational judgment and reduces the delay in signal transmission for a data series in which it is difficult to distinguish between encoding and edge encoding in determining an excessive input signal.

In other words, the isolator 100 according to the first embodiment can reduce power consumption and delay in signal transmission.

### Second Embodiment

In the first embodiment described above, an example of the configuration of an isolator was explained. However, the configuration of this isolator is not limited to this. Therefore, in this second embodiment, we will explain the configuration of an isolator that reduces the delay in determining an excessive input signal (demodulation of demodulation attribute information indicating the second attribute) in the demodulation circuit when the input analog signal VIN is detected as an excessive input signal.

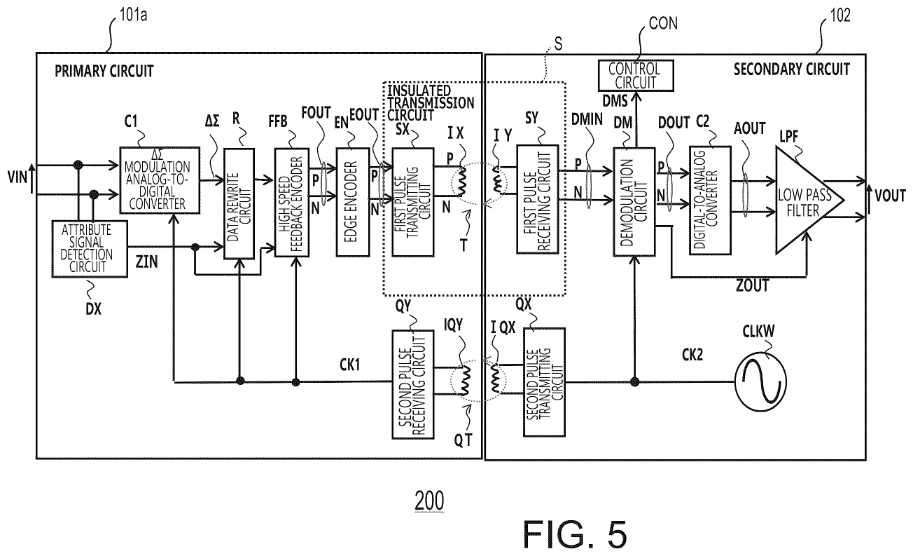

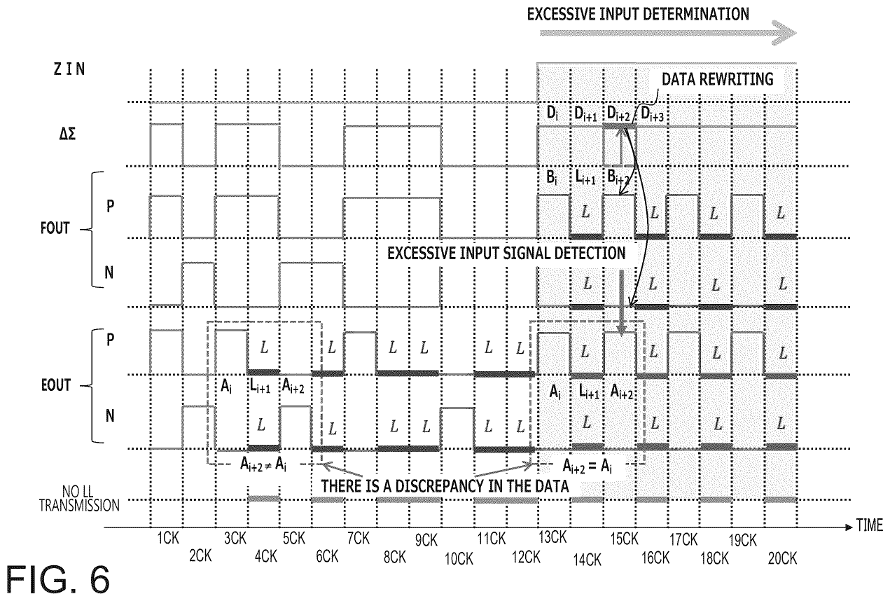

FIG. 5 is a diagram showing an example of the configuration of an isolator according to the second embodiment. FIG. 6 is a diagram showing an example of a signal waveform in the isolator shown in FIG. 5. In the description of the isolator according to the second embodiment, the description of components having the same reference numerals as those in the first embodiment will be omitted.

As shown in FIG. 5, the isolator 200 according to the second embodiment further includes a data rewrite circuit R in the primary circuit 101a, compared to the isolator 100 shown in FIG. 1 described above.

The data rewrite circuit R is arranged, for example, between the ΔΣ modulation analog-to-digital converter C1 and the high speed feedback encoder FFB, as shown in FIG. 5.

This data rewrite circuit R rewrites part of the data of the digital data signal ΔΣ output by the ΔΣ modulation analog-digital converter C1 according to the input attribute information ZIN, and outputs this rewritten data to the high speed feedback encoder FFB.

For example, when the input attribute information ZIN indicates a first attribute in which the input analog signal VIN is a normal data signal, the data rewrite circuit R outputs the input digital data signal ΔΣ as is to the high speed feedback encoder FFB.

On the other hand, when the input attribute information ZIN indicates the second attribute that the input analog signal VIN is an excessive input signal, and the data series of the digital data signal ΔΣ contains data that is temporarily inverted from the first polarity “H” to the second polarity “L”, the data rewrite circuit R rewrites the polarity of the inverted data from the second polarity “L”to the first polarity “H”.

Here, when the input analog signal VIN is a positive excessive input signal, the ΔΣ modulation analog-to-digital converter C1 ideally outputs a digital data signal ΔΣ of the data series of the first polarity “H”.

However, for example, as shown at time 15CK in FIG. 6, when the input attribute information ZIN is the first polarity “H” indicating the second attribute that the input analog signal VIN is an excessive input signal, due to a design problem of the ΔΣ modulation analog-to-digital converter C1, the data series (Dᵢ to Dᵢ₊₃) of the digital data signal ΔΣ may contain data Dᵢ₊₂ that is temporarily inverted from the first polarity “H”to the second polarity “L”.

When this input attribute information ZIN is the first polarity “H” indicating the second attribute, the inversion of the polarity of the digital data signal ΔΣ is not the desired operation of the ΔΣ modulation analog-to-digital converter C1.

Then, when the input analog signal VIN described above is an excessive input signal, that is, when the data of the input attribute information ZIN is of the first polarity “H” indicating the second attribute, if the data of the digital data signal ΔΣ is fixed at “H”, then unless the number of periods M of the refresh cycle is set to 2, this data series indicates an excessive input signal, that is, it is a data series when the data of the input attribute information ZIN is of the first polarity “H” indicating the second attribute. It is noted that the number of periods M is not normally set to 2.

It is noted that when the data of input attribute information zin is of the first polarity “H” indicating the second attribute, if the data of digital data signal ΔΣ is fixed at “L”, then unless the number of cycles M of the refresh cycle is set to 2, this data series is an excessive input signal, that is, a data series when the data of input attribute information ZIN is of the first polarity “H” indicating the second attribute. Here, fixed at “L”means a negative excessive input.

Here, as shown in FIG. 6, depending on the design of the ΔΣ modulation analog-to-digital converter C1, there are cases where the digital data signal ΔΣ is not fixed to “H” or “L” even when the data of the input attribute information ZIN is of the first polarity “H”. In this case, when the transmission signal DMIN is observed in the demodulation circuit DM, there is a possibility that the data of the input attribute information ZIN is of both the first polarity “H” and the second polarity “L”.

To avoid this possibility, in the second embodiment, when an excessive input signal is detected, i.e., when the data of the input attribute information ZIN is of the first polarity “H”, the digital data signal ΔΣ is fixed for the period during which the data of the input attribute information ZIN remains “H”. This allows the demodulation circuit DM to demodulate the demodulation attribute information corresponding to the input attribute information ZIN shown in FIG. 6, which indicates the presence or absence of excessive input, based on the transmission signal DMIN corresponding to the second encoded signal EOUT shown in FIG. 6.

As shown in FIG. 6, when the data of the digital data signal ΔΣ changes from “H” to “L” at the third clock (time CK15) after the detection of an excessive input signal, and the data becomes “H” after the fourth clock (time CK16), the data rewrite of the digital data signal ΔΣ of the second embodiment is applied.

By rewriting the data D}rsub{i+}¿ of the digital data signal ΔΣ at the third clock (time 15 CK) from “L” to “H”, the first encoded signal FOUT and the second encoded signal EOUT change accordingly.

At the P terminal of the output of the second encoded signal EOUT, the data on both ends of the data “L” is “H”, and the demodulation circuit DM can determine the excessive input signal and demodulate the demodulation attribute information ZOUT based on the transmission signal DMIN corresponding to the second encoded signal EOUT.

As described above, as shown in FIG. 6, if the data on both sides of the 2-bit second encoded signal EOUT with a predetermined value of data “LL” are the same value, the input attribute information ZIN is uniquely determined. Taking advantage of this point, when the input attribute information is determined to be the second attribute indicating an excessive input signal, the data of the digital data signal ΔΣ at that time is fixed until the state in which the input analog signal VIN is an excessive input signal ends.

This allows the input attribute information to be uniquely determined in the demodulation circuit DM. In this case, the data of the digital data signal ΔΣ is intentionally changed, but the data of the digital data signal ΔΣ when the input signal is excessive may be set to a fixed value. Therefore, it is considered that there will be no problems due to changes in the data of the digital data signal ΔΣ.

The rest of the configuration and operation of the isolator 200 of the second embodiment are similar to the configuration and operation of the isolator 100 of the first embodiment.

In other words, the isolator according to the second embodiment can reduce power consumption and reduce delays in signal transmission.

### Third Embodiment

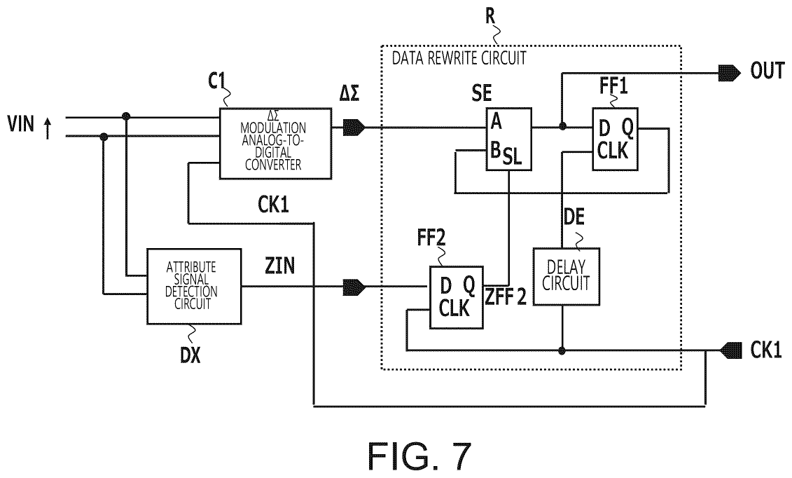

FIG. 7 is a diagram showing an example of a specific configuration of the data rewrite circuit R of the isolator 200 shown in FIG. 5. It is noted that the data rewrite circuit R shown in FIG. 7 is an example of the configuration of the data rewrite circuit R applied to the isolator 200 according to the second embodiment described above, and is not limited to this.

For example, as shown in FIG. 7, the data rewrite circuit R includes a selector SE, two flip-flops FF1 and FF2, and a delay circuit DE.

The input attribute information ZIN output by the attribute signal detection circuit DX is input to flip-flop FF2 of the data rewrite circuit R. Then, flip-flop FF2 converts the input attribute information ZIN into attribute signal information ZFF2 synchronized with the first clock signal CK1 output from the second pulse receiving circuit QY, and outputs the attribute signal information ZFF2.

The delay circuit DE outputs a clock signal, that is a delayed version of the first clock signal CK1, to the flip-flop FF1.

Flip-flop FF1 converts the signal selected and output by selector SE into a signal synchronized with the clock signal output from delay circuit DE, and outputs the converted signal.

The selector SE selects and outputs either the current digital data signal ΔΣ (A) or the digital data signal (B) output ½ clock earlier by flip-flop FF1, depending on the attribute signal information ZFF2.

For example, when the attribute signal information ZFF2=“L”, the selector SE selects and outputs the current digital data signal ΔΣ.

On the other hand, when the attribute signal information ZFF2 is “H”, the selector SE selects and outputs the digital data signal output ½ clock before by the flip-flop FF1.

Then, the output signal OUT output by the selector SE, which is the output of the data rewrite circuit R, is input to the high speed feedback encoder FFB located in the next stage shown in FIG. 5.

Here, as already mentioned, the judgment on the data series of the PN terminal of the second encoded signal EOUT is shown in FIG. 4 already mentioned.

In order to solve the problem of not being able to identify attribute information in the judgment shown in FIG. 4, for a data series in which one LL transmission is inserted between data, if Aᵢ₊₂=Aᵢ, it is judged to be an excessive input signal, and if Aᵢ₊₂=Āᵢ, it is judged to be a normal signal, and the signal attributes are demodulated. To achieve this operation, in the isolator described in the second embodiment above, a data rewrite circuit R as shown in FIG. 7 is provided between the analog-to-digital converter C1 and the high speed feedback encoder FFB. This executes an operation to fix the data of the digital data signal ΔΣ during excessive input to the data when an excessive input signal occurred.

### Fourth Embodiment

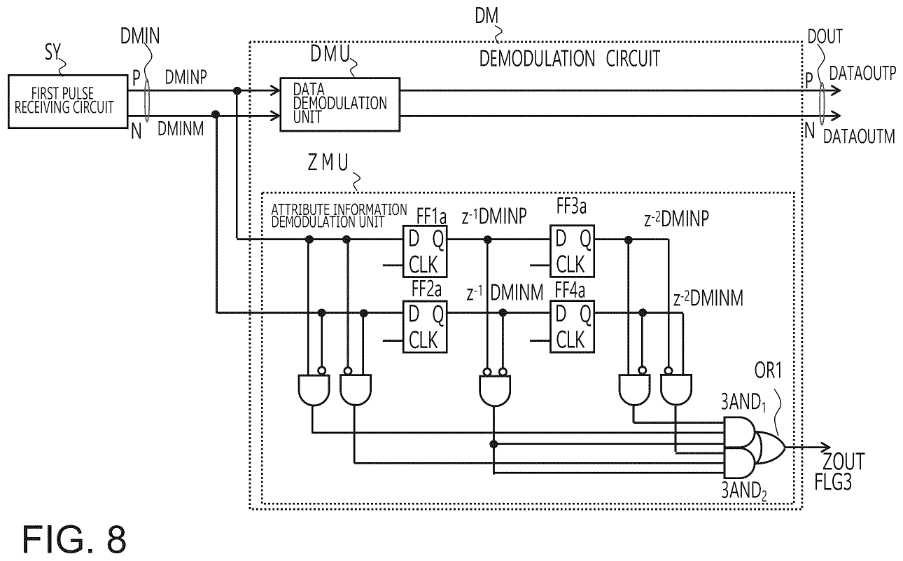

FIG. 8 is a diagram showing an example of a specific configuration of the demodulation circuit of the isolator shown in FIG. 5. It is noted that the demodulation circuit DM shown in FIG. 8 is an example of the configuration of the demodulation circuit DM applied to the isolator 200 according to the second embodiment described above, and is not limited to this.

For example, as shown in FIG. 8, the demodulation circuit DM comprises a data demodulation unit DMU and an attribute information demodulation unit ZMU.

Then, as shown in FIG. 8, the transmission signal DMIN (DMINP, DMINM) output by the first pulse receiving circuit SY is input separately to the data demodulation unit DMU and the attribute information demodulation unit ZMU.

The data demodulation unit DMU uses edge encoding demodulation, for example, to treat the transmission signal DMIN (DMINP, DMINM) as “LL” and the data as being the same as the previous data. Alternatively, the data demodulation unit DMU may treat the “LL” of the transmission signal DMIN (DMINP, DMINM) as a thinned signal and use signal interpolation techniques on the thinned signal to regenerate the signal.

On the other hand, as described above, if the data before and after “LL” of the transmission signal DMIN (DMINP, DMINM) are Aᵢ, Aᵢ₊₂, then the attribute information demodulation unit ZMU only needs to have a relationship of Aᵢ₊₂=Aᵢ□ for both the positive and negative terminals.

It is noted that in FIG. 8, if the current output of the first pulse receiving circuit SY is DMINP and DMINM, the outputs of flip-flops FF1a and FF2a are represented by data z⁻¹DMINP and z⁻¹DMINM, respectively, which are data from one clock before, and the outputs of flip-flops FF3aand FF4a are represented by data z⁻²DMINP and z⁻²DMINM, respectively, which are data from two clocks before.

The data from one clock ago, z⁻¹DMINP and z⁻¹DMINM, are both “L”, and it is necessary to detect the case where the current data and the data from two clocks ago are not both “LL” but have the same code, i.e., “HL”or “LH”.

Then, the AND circuit 3AND₁ detects “HL-LL-HL” and outputs a signal according to this detection.

Furthermore, the AND circuit 3AND₂ detects “LH-LL-LH” and outputs a signal according to this detection.

Then, the OR circuit OR1 performs an OR operation on the signals output by these AND circuits 3AND₁ and 3AND₂, thereby outputting demodulated attribute information ZOUT indicating attribute information related to the excessive input signal.

For example, if the demodulation attribute information ZOUT=“H”, it is determined that an excessive input signal has been detected, and if the demodulation attribute information ZOUT=“L”, it is determined that a normal data signal has been input.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An isolator comprising:
a ΔΣ modulation analog-to-digital converter that receives an input analog signal, converts the input analog signal into a digital data signal of a pulse train corresponding to the amplitude of the input analog signal, and outputs the digital data signal;
an attribute signal detection circuit that detects an attribute of the input analog signal and outputs input attribute information related to the attribute of the input analog signal;
a high speed feedback encoder that encodes the digital data signal based on the input attribute information and outputs a first encoded signal;
an edge encoder that receives the first encoded signal, edge-encodes the first encoded signal, and outputs a second encoded signal;
an insulated transmission circuit that has an insulation unit electrically insulated between an input and an output, receives the second encoded signal, and outputs a transmission signal transmitted through the insulation unit in response to the second encoded signal; and
a demodulation circuit that receives the transmission signal, and outputs a demodulated digital data signal obtained by demodulating the second encoded signal and/or the input attribute information, based on the transmission signal.

2. The isolator according to claim 1,
wherein, when the amplitude of the input analog signal is equal to or less than an excessive threshold set based on the input range of the ΔΣ modulation analog-to-digital converter, the attribute signal detection circuit outputs input attribute information indicating a first attribute that the input analog signal is a normal data signal input, and,
wherein, when the amplitude of the input analog signal is greater than the excessive threshold, the attribute detection circuit outputs input attribute information indicating a second attribute that the input analog signal is an excessive input signal.

3. The isolator described in claim 1,
wherein, if a first data series of the second encoded signal obtained by encoding a digital data signal corresponding to input attribute information indicating the first attribute by the edge encoder is the same as a second data series of the second encoded signal obtained by encoding a digital data signal corresponding to input attribute information indicating the second attribute by the edge encoder,
the demodulation circuit outputs a demodulated digital data signal demodulated as a data series of an input analog signal of a normal data signal based on a data series of the transmission signal corresponding to the second encoded signal of the second data series.

4. The isolator according to claim 2,
wherein, if a first data series of the second encoded signal obtained by encoding a digital data signal corresponding to input attribute information indicating the first attribute by the edge encoder is the same as a second data series of the second encoded signal obtained by encoding a digital data signal corresponding to input attribute information indicating the second attribute by the edge encoder,
the demodulation circuit outputs a demodulated digital data signal demodulated as a data series of an input analog signal of a normal data signal based on a data series of the transmission signal corresponding to the second encoded signal of the second data series.

5. The isolator according to claim 1, wherein a first clock signal that determines the operation of the ΔΣ modulation analog-to-digital converter and the high speed feedback encoder is synchronized with a second clock signal that determines the operation of the demodulation circuit.

6. The isolator described in claim 2, wherein a first clock signal that determines the operation of the ΔΣ modulation analog-to-digital converter and the high speed feedback encoder is synchronized with a second clock signal that determines the operation of the demodulation circuit.

7. The isolator described in claim 3, wherein a first clock signal that determines the operation of the ΔΣ modulation analog-to-digital converter and the high speed feedback encoder is synchronized with a second clock signal that determines the operation of the demodulation circuit.

8. The isolator according to claim 3,
wherein the high speed feedback encoder outputs a first encoded signal encoded according to the polarity of the data series of the digital data signal when the input attribute information indicates the first attribute, and
wherein the high speed feedback encoder outputs a first encoded signal encoded according to the polarity of the data series of the digital data signal, in which some data has been forcibly rewritten to a predetermined value, when the input attribute information indicates the second attribute.

9. The isolator according to claim 4,
wherein the high speed feedback encoder outputs a first encoded signal encoded according to the polarity of the data series of the digital data signal when the input attribute information indicates the first attribute, and
wherein the high speed feedback encoder outputs a first encoded signal encoded according to the polarity of the data series of the digital data signal, in which some data has been forcibly rewritten to a predetermined value, when the input attribute information indicates the second attribute.

10. The isolator according to claim 5,
wherein the high speed feedback encoder outputs a first encoded signal encoded according to the polarity of the data series of the digital data signal when the input attribute information indicates the first attribute, and
wherein the high speed feedback encoder outputs a first encoded signal encoded according to the polarity of the data series of the digital data signal, in which some data has been forcibly rewritten to a predetermined value, when the input attribute information indicates the second attribute.

11. The isolator according to claim 8,
wherein, data before and after the rewrite data of the predetermined value are first data and second data, and
when a polarity of the first data and a polarity of the second data are equal, the demodulation circuit determines that the input attribute information indicates a second attribute that the input analog signal is an excessive input signal, and outputs demodulation attribute information according to this determination result.

12. The isolator according to claim 9,
wherein, data before and after the rewrite data of the predetermined value are first data and second data, and
when a polarity of the first data and a polarity of the second data are equal, the demodulation circuit determines that the input attribute information indicates a second attribute that the input analog signal is an excessive input signal, and outputs demodulation attribute information according to this determination result.

13. The isolator according to claim 10,
wherein, data before and after the rewrite data of the predetermined value are first data and second data, and
when a polarity of the first data and a polarity of the second data are equal, the demodulation circuit determines that the input attribute information indicates a second attribute that the input analog signal is an excessive input signal, and outputs demodulation attribute information according to this determination result.

14. The isolator according to claim 1, further comprising a data rewrite circuit arranged between the ΔΣ modulation analog-to-digital converter and the high speed feedback encoder, which rewrites a part of the data of the digital data signal output by the ΔΣ modulation analog-to-digital converter in accordance with the input attribute information and outputs the rewritten data to the high speed feedback encoder,
wherein, when the input attribute information indicates a first attribute in which the input analog signal is a normal data signal, the data rewrite circuit outputs the input digital data signal as is to the high speed feedback encoder, and
wherein, when the input attribute information indicates a second attribute in which the input analog signal is an excessive input signal, the data rewrite circuit rewrites the polarity of the inverted data when the data series of the digital data signal includes temporarily inverted data.

15. The isolator according to claim 2, further comprising a data rewrite circuit arranged between the ΔΣ modulation analog-to-digital converter and the high speed feedback encoder, which rewrites a part of the data of the digital data signal output by the ΔΣ modulation analog-to-digital converter in accordance with the input attribute information and outputs the rewritten data to the high speed feedback encoder,
wherein, when the input attribute information indicates a first attribute in which the input analog signal is a normal data signal, the data rewrite circuit outputs the input digital data signal as is to the high speed feedback encoder, and
wherein, when the input attribute information indicates a second attribute in which the input analog signal is an excessive input signal, the data rewrite circuit rewrites the polarity of the inverted data when the data series of the digital data signal includes temporarily inverted data.

16. The isolator according to claim 3, further comprising a data rewrite circuit arranged between the ΔΣ modulation analog-to-digital converter and the high speed feedback encoder, which rewrites a part of the data of the digital data signal output by the ΔΣ modulation analog-to-digital converter in accordance with the input attribute information and outputs the rewritten data to the high speed feedback encoder,
wherein, when the input attribute information indicates a first attribute in which the input analog signal is a normal data signal, the data rewrite circuit outputs the input digital data signal as is to the high speed feedback encoder, and
wherein, when the input attribute information indicates a second attribute in which the input analog signal is an excessive input signal, the data rewrite circuit rewrites the polarity of the inverted data when the data series of the digital data signal includes temporarily inverted data.

17. The isolator according to claim 4, further comprising a data rewrite circuit arranged between the ΔΣ modulation analog-to-digital converter and the high speed feedback encoder, which rewrites a part of the data of the digital data signal output by the ΔΣ modulation analog-to-digital converter in accordance with the input attribute information and outputs the rewritten data to the high speed feedback encoder,
wherein, when the input attribute information indicates a first attribute in which the input analog signal is a normal data signal, the data rewrite circuit outputs the input digital data signal as is to the high speed feedback encoder, and
wherein, when the input attribute information indicates a second attribute in which the input analog signal is an excessive input signal, the data rewrite circuit rewrites the polarity of the inverted data when the data series of the digital data signal includes temporarily inverted data.

18. The isolator according to claim 1,
wherein the insulated transmission circuit transmits a transmission signal of a pulse of a data series of data of a first polarity or a second polarity synchronized with a first clock signal in response to the second encoded signal, or
wherein the insulated transmission circuit transmits a transmission signal that does not include a pulse within a predetermined clock period defined by the first clock signal in response to the second encoded signal.

19. The isolator according to claim 2,
wherein the insulated transmission circuit transmits a transmission signal of a pulse of a data series of data of a first polarity or a second polarity synchronized with a first clock signal in response to the second encoded signal, or
wherein the insulated transmission circuit transmits a transmission signal that does not include a pulse within a predetermined clock period defined by the first clock signal in response to the second encoded signal.

20. The isolator according to claim 3,
wherein the insulated transmission circuit transmits a transmission signal of a pulse of a data series of data of a first polarity or a second polarity synchronized with a first clock signal in response to the second encoded signal, or
wherein the insulated transmission circuit transmits a transmission signal that does not include a pulse within a predetermined clock period defined by the first clock signal in response to the second encoded signal.
